(19) United States
(12) Patent Application Publication
(10) Pub. No.: US 2015/0123150 A1
(43) Pub. Date: May 7, 2015

(54) DISPLAY DEVICE

(71) Applicant: Japan Display Inc., Tokyo (JP)

(72) Inventor: Masaya ADACHI, Tokyo (JP)

(73) Assignee: Japan Display Inc.

(21) Appl. No.: 14/532,069

(22) Filed: Nov. 4, 2014

(30) Foreign Application Priority Data
Nov. 6, 2013 (JP) 2013-230511

(51) Int. Cl. H01L 27/32

(52) U.S. Cl. CPC H01L 27/3246; H01L 27/3213
USPC 257/88

(57) ABSTRACT

When the plane shape of a bank edge, that is, the direction of a line segment connecting the centers of pixels adjacent to each other (the direction of the pixels) is orthogonal to the direction of a line segment formed by the bank edge, light leaks from the adjacent pixels. The shape of the luminous region of the pixel of a display device, that is, the edge shape of a bank opening is formed as follows. The direction of an approximately linear portion (a line segment) formed by a bank edge is not orthogonal to the direction of the most closely adjacent pixel (an acute angle or an obtuse angle is formed by the directions).

### CLAIM OF PRIORITY

The present application claims priority from Japanese Patent Application JP2013-230511 filed on Nov. 6, 2013, the content of which is hereby incorporated by reference into this application.

### BACKGROUND

The present disclosure relates to a display device, and is applicable to a display device including a light emitting element, for example.

The organic light-emitting diode (OLED) element is an element that injects positive and negative electric charges into a light emitting layer formed of an organic thin film and converts electric energy into optical energy for emitting light. Since a luminous display device including an organic light-emitting diode element as a light emitting element (in the following, referred to as “an OLED display device”) is a self-luminous type, which is different from a non-luminous display device typified by a liquid crystal display device, an auxiliary light source such as a backlight is unnecessary, and the OLED display is reduced in the thickness and in the weight. Moreover, the OLED display device has characteristics including a wide viewing angle and a quick display response speed.

On the other hand, in the OLED display device, a bank formed of a thick film made of an organic insulating material is formed on a lower electrode, for example. The bank has an embankment structure or an isolation structure between pixels adjacent to each other in which a light emission portion (also referred to as a luminous region or a light emission area) is formed so as to expose a part of a lower electrode, and the bank defines the light emission area of a light emitting element (a light emitting layer) configuring a pixel. Such a structure is provided in which the light emitting layer is formed on the bank and the lower electrode and the light emitting layer is covered with an upper electrode. The lower electrode is isolated from the upper electrode by the bank on the periphery of the light emission area. Light generated in a certain pixel sometimes leaks as stray light from the other pixel regions adjacent to the pixel caused by an insulating film (a so-called bank layer) that separates the luminous region of the OLED display device between pixels. It is disclosed that a bank is formed of an inorganic insulating film in a thin film thickness in a slightly tapered shape and light leakage from the adjacent pixels is prevented. (See Japanese Unexamined Patent Application Publication No. 2005-5227)

### SUMMARY

The inventors of the present application found that the situations of light leakage from the adjacent pixels are changed depending on the plane shape of the bank edge.

In other words, when the plane shape of the bank edge disclosed in Japanese Unexamined Patent Application Publication No. 2005-5227 is provided, that is, when the direction of a line segment connecting the centers of pixels adjacent to each other is orthogonal to the direction of a line segment formed by a bank edge, much more light leakage occurs.

The other problems and novel features will be apparent from the description and accompanying drawings of the present disclosure.

The following is a brief description of the outline of a representative aspect of the present disclosure.

In other words, the shape of the luminous region of a pixel of a display device, that is, the edge shape of a bank opening is formed as follows. The direction of an approximately linear portion (a line segment) formed by a bank edge is not orthogonal to the direction of the most closely adjacent pixel (an acute angle or an obtuse angle is formed by the directions).

According to the display device, it is possible to suppress light leakage caused by a bank shape.

### BRIEF DESCRIPTION OF THE DRAWINGS

FIG. 1 is a schematic cross sectional view of the vicinity of a single pixel of a display device according to an embodiment;

FIG. 2 is a schematic block diagram of the overall layout of the display device according to the embodiment;

FIG. 3 is an equivalent circuit diagram of an active matrix array configuring a display unit according to the embodiment;

FIG. 4A is a partial plan view of the display unit according to the embodiment;

FIG. 4B is a partial plan view of a display unit according to a first exemplary modification;

FIG. 4C is a partial plan view of a display unit according to a second exemplary modification;

FIG. 4D is a partial plan view of a display unit according to a third exemplary modification;

FIG. 5 is a partial plan view of a display unit according to a fourth exemplary modification;

FIG. 6 is a plan view of the schematic structure of an OLED display device according to a comparative example;

FIG. 7A is a diagram of a result that the situations of light leakage according to the comparative example are optically simulated;

FIG. 7B is a diagram of bank opening shapes in FIG. 7A;

FIG. 8 is a schematic cross sectional diagram of a partial schematic structure of the OLED display device according to the comparative example;

FIG. 9 is a schematic diagram of a partial cross section of the schematic structure of a light leakage prevention structure according to the embodiment;

FIG. 10 is a schematic diagram of a partial cross section of the schematic structure of a light extraction structure according to the first exemplary modification;

FIG. 11A is a diagram of bank opening shapes;

FIG. 11B is a diagram of bank opening shapes;

FIG. 11C is a diagram of bank opening shapes;

FIG. 11D is a diagram of bank opening shapes;

FIG. 11E is a diagram of bank opening shapes;

FIG. 11F is a diagram of bank opening shapes; and

FIG. 11G is a diagram of bank opening shapes.

### DESCRIPTION OF THE PREFERRED EMBODIMENTS

In the following, a comparative example, an embodiment, and exemplary modifications will be described with reference to the drawings. However, in the following description, the same components are designated the same reference numerals and signs, and the overlapping description is omitted.

Technique Investigated prior to the Present Disclosure

In the OLED display device, generally, an insulating layer (in the following, referred to as a bank) covers the peripheral part of a lower electrode configuring a light emitting element (an organic light-emitting diode element) and a non-luminous portion, and the opening of the bank corresponds to a luminous region. Moreover, the surface of a display unit including the light emitting element and the bank are covered with a transparent sealing material, a transparent substrate is disposed above the transparent sealing material, and the gap is filled with a transparent filler for solid sealing.

Pixels are disposed in a matrix configuration, the shape of the luminous regions of the pixels is generally based on a rectangular shape, and the bank is formed in a nearly grid shape having nearly rectangular openings. The inventors investigated that in the OLED display device in this structure, a white organic light-emitting diode element is used for a light emitting element, and a full color display device is implemented by providing color filters of three primary colors in red (R), green (G), and blue (B), or by providing a white (W) color filter in addition to red, green, and blue filters on the light extraction side of the light emitting element.

In this OLED display device, there is concern that when red monochrome color is displayed, for example, the chromaticity does not take the value expected from the emission spectrum of the light emitting element and the transmittance of the red filter, and color purity is degraded. The degradation of color purity of primary colors (monochrome colors) causes concern about a reduction in the range of color reproduction of the display device.

As a result of investigating the cause, it was reveled that light leaks from the region of a pixel that has a color different from the color of a pixel for a desired color and that does not have to emit light originally. As a result of analysis, it was revealed that light leakage from the non-luminous pixel is caused by the bank. In the following, light leakage in a technique investigated prior to the present disclosure will be described (in the following, referred to as a comparative example).

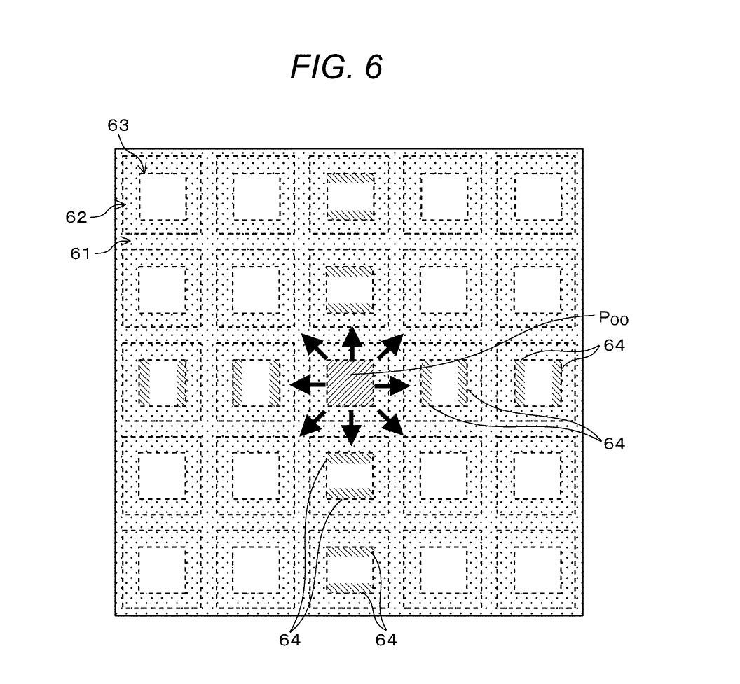

FIG. 6 is a plan view of the schematic structure of an OLED display device according to a comparative example. The shape of a lower electrode 62 (in the following, also referred to as a pixel electrode 62) is in a rectangular shape, the shape of a pixel opening 63 is also in a rectangular shape, and the pixel opening 63 is smaller than the pixel electrode. A bank 61 covers the pixel electrode 62 or the like except the pixel opening 63. In the comparative example, since light leaks from non-luminous pixels adjacent to a luminous pixel P₀₀, and the degradation of color purity occurs or a blur occurs in display. Light leakage portions 64 are illustrated in FIG. 6.

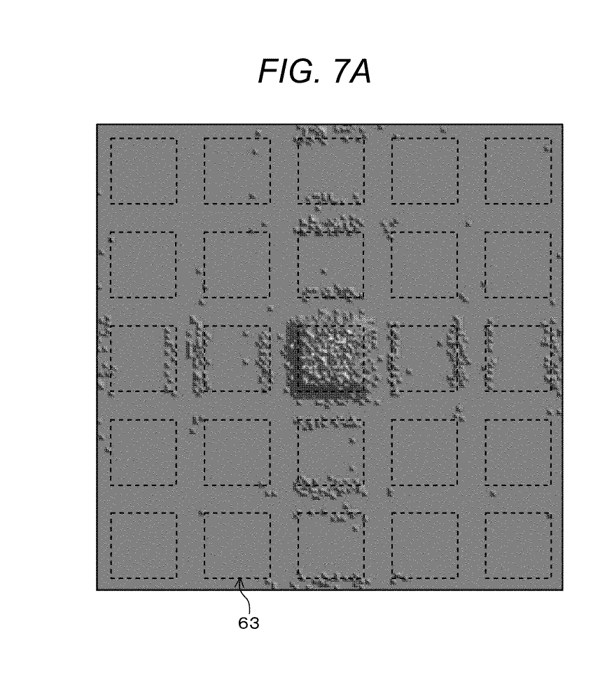

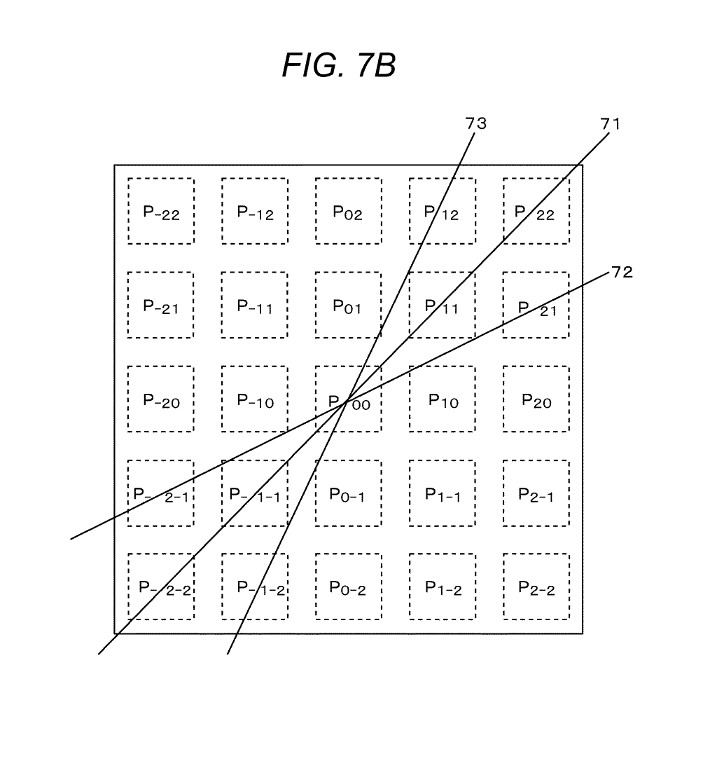

FIG. 7A is a diagram of a result that the situations of light leakage according to the comparative example are optically simulated, showing the luminance distribution (isoluminance contours) in a plane in a region of five sub-pixels high and five sub-pixels wide, in the case where light is emitted only from a sub-pixel in the center. FIG. 7B is a diagram of bank opening shapes in FIG. 7A. It is shown that light leaks from near the edges (the bank edges) of the bank openings 62 of pixels P₁₀, P₀₁, P₀₋₁, and P₋₁₀ adjacent to the luminous pixel P₀₀. Moreover, light also leaks from near the bank edges of pixels P₂₀, P₀₂, P₋₂₀, and P₀₋₂ other than the pixels adjacent to the luminous pixel P₀₀. On the other hand, the amount of light leakage is small in pixels P₁₁, P₂₂, P₂₁, and P₁₂ located diagonally to the upper right of the luminous pixel P₀₀, in pixels P₁₋₁, P₂₋₀, P₂₋₁, and P₁₋₂ located diagonally to the lower right of the luminous pixel P₀₀, in pixels P ₋₁₋₁, P₋₂₋₂, P₋₂₋₁, and P₋₁₋₂ located diagonally to the lower left of the luminous pixel P₀₀, and in pixels P₋₁₁, P₋₂₂, P₋₂₁, and P₋₁₂ located diagonally to the upper left of the luminous pixel P₀₀.

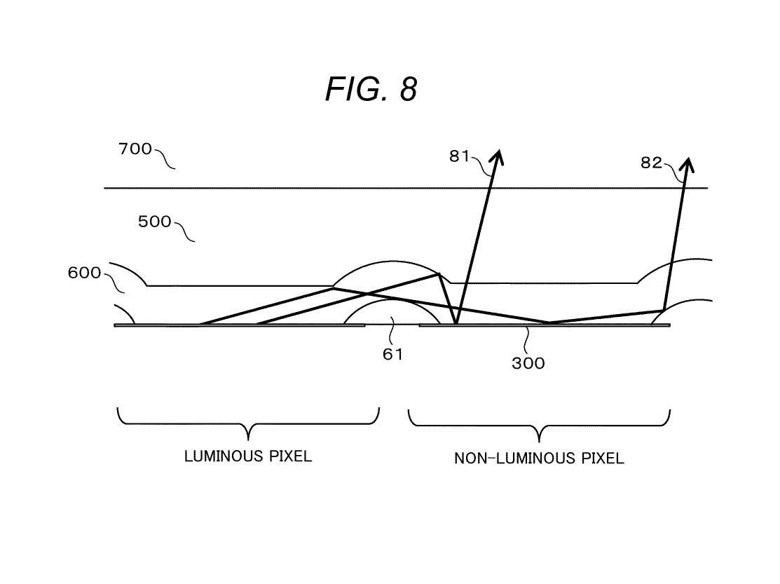

FIG. 8 is an illustration of the light leakage phenomenon, and a schematic cross sectional diagram of a partial schematic structure of the OLED display device. As illustrated in FIG. 8, light leaks mainly on a path (a first path) 81 caused by reflection on the interface between a sealing material 600 and a filler 500 in a projection following the shape of the bank 61 and on a path (a second path) 82 caused by reflection on the interface between the sealing material 600 and the bank 61, and both are caused by the shape of the bank.

Moreover, as a result of the investigation of the comparative example, the inventors found findings below. As illustrated in FIG. 7A, a greater amount of light leaks from the pixels arranged in the vertical direction and in the lateral direction to the luminous pixel. In other words, in the pixels adjacent to the luminous pixel, light mainly leaks in the region in which the direction of an approximately linear bank edge (in the following, also referred to as a line segment) is nearly orthogonal to the direction of the luminous pixel. On the other hand, a small amount of light leaks in the adjacent pixels located in the oblique direction to the luminous pixel.

In other words, in the non-luminous pixels adjacent to the luminous pixel, light does not leak so much in the pixels in which the direction of the line segment formed by the bank edge is tilted at an angle including an angle of 45° (at an angle ranging from about 30° to 60°) with respect to the direction of the luminous pixel. In other words, light does not leak so much in the pixels in which an angle formed by the direction of the line segment connecting the center of the non-luminous pixel to the center of the luminous pixel and the direction of the line segment formed by the bank edge of the non-luminous pixel is tilted at an angle including an angle of 45° (at an angle of about 27° to 63°). For example, an angle formed by the direction of a line segment 71 connecting the center of the non-luminous pixel P₁₁ to the center of the luminous pixel P₀₀ and the direction of a line segment formed by the bank edge of the non-luminous pixel P₁₁ is an angle of about 45°. An angle formed by the direction of a line segment 72 connecting the center of the non-luminous pixel P₂₁ to the center of the luminous pixel P₀₀ and the direction of a line segment formed by the bank edge of the non-luminous pixel P₂₁ is an angle of about 27° or 63°. An angle formed by the direction of a line segment 73 connecting the center of the non-luminous pixel P₂₁ to the center of the luminous pixel P₀₀ and the direction of a line segment formed by the bank edge of the non-luminous pixel P₂₁ is an angle of about 27° or 63°.
(1) The shape of the luminous region of the pixel, that is, the edge shape of the bank opening is defined as follows. Such a bank opening shape is formed in which the direction of an approximately linear portion (a line segment) formed by the bank edge is not orthogonal to the direction of two pixels most closely adjacent to each other and located as sandwiching a pixel having the bank opening (an acute angle or an obtuse angle is formed by the directions). More desirably, such a bank opening shape is formed in which the direction of the line segment formed by the bank edge forms an angle ranging from 27° to 63° (or 117° to 153°) with the direction of the most closely adjacent pixels. More specifically, the shape of the luminous region of the pixel, that is, the edge shape of the bank opening is formed in a planar structure based on a rectangle in which the vertices of the pixels adjacent to each other face each other.
(2) In structure 1, a light leakage prevention structure having projections and depressions is formed between pixels whose approximately linear bank edges face each other. In the light leakage prevention structure, an approximately linear portion in the outline of the projections and depressions is formed nearly in parallel with the direction of the approximately linear portion formed by the edge of the bank opening.
(3) In structure 1, a light extraction structure having projections and depressions is formed in the luminous region of a pixel. In the light extraction structure, an approximately linear portion of the outline of the projections and depressions is formed nearly in parallel with the direction of the approximately linear portion formed by the edge of the bank opening.

As a result of the investigation, it was found that light leakage from the non-luminous pixel mainly occurs in the region in which the direction of the edge of the bank opening, that is, the direction of an approximately linear portion (a line segment) formed by the bank edge is orthogonal to a light source, that is, the direction of the luminous pixel.

Moreover, it was found that in the non-luminous pixels adjacent to the luminous pixel, light does not leak so much in the pixel in which the direction of the line segment formed by the bank edge is tilted at an angle of about 27° to 63° with respect the direction of the luminous pixel. On this account, with the adaption of structure 1, in the motet closely adjacent pixels, the direction of the line segment formed by the bank edge is not orthogonal to the direction of the next pixel, and is tilted to the next pixel, so that it is possible to suppress light leakage caused by a bank shape.

Because of the adoption of structure 1, although light leakage from the most closely adjacent pixels can be suppressed, it is likely that light leaks in the pixels whose directions of the line segments formed by the bank edges are in parallel with each other. However, with the adaption of structure 2, the light leakage prevention structure having projections and depressions changes the direction of light between the pixels adjacent to each other whose directions of the line segments formed by the bank edges are in parallel with each other, and the light is absorbed into a black matrix, so that light leakage to the next pixel can be suppressed.

In the case where the light extraction structure having projections and depressions, for example, is formed in the luminous region of the pixel, there is concern that light emitted from the adjacent pixel is extracted by the light extraction structure to be leakage light. However, when the light extraction structure is formed like the structure (3), light extraction from the adjacent pixel can be suppressed, so that it is possible to reduce light leakage.

Light leakage from the adjacent pixels can be suppressed, so that it is possible to implement a display device with less color mixture or less blurred display. Moreover, the light extraction structure that suppresses leakage light is realized, so that it is possible to implement a brighter display device with a wider range of color reproduction

### Embodiment

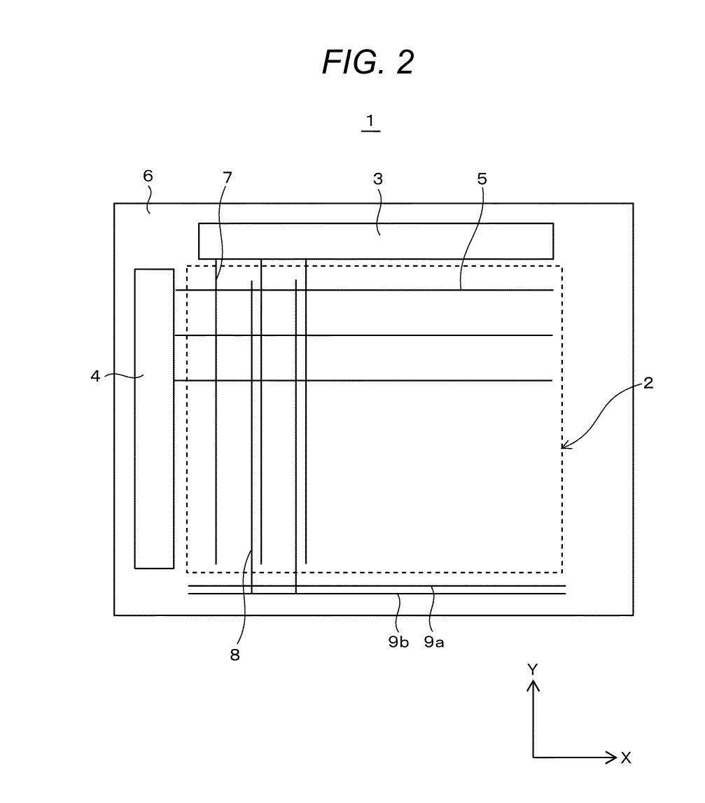

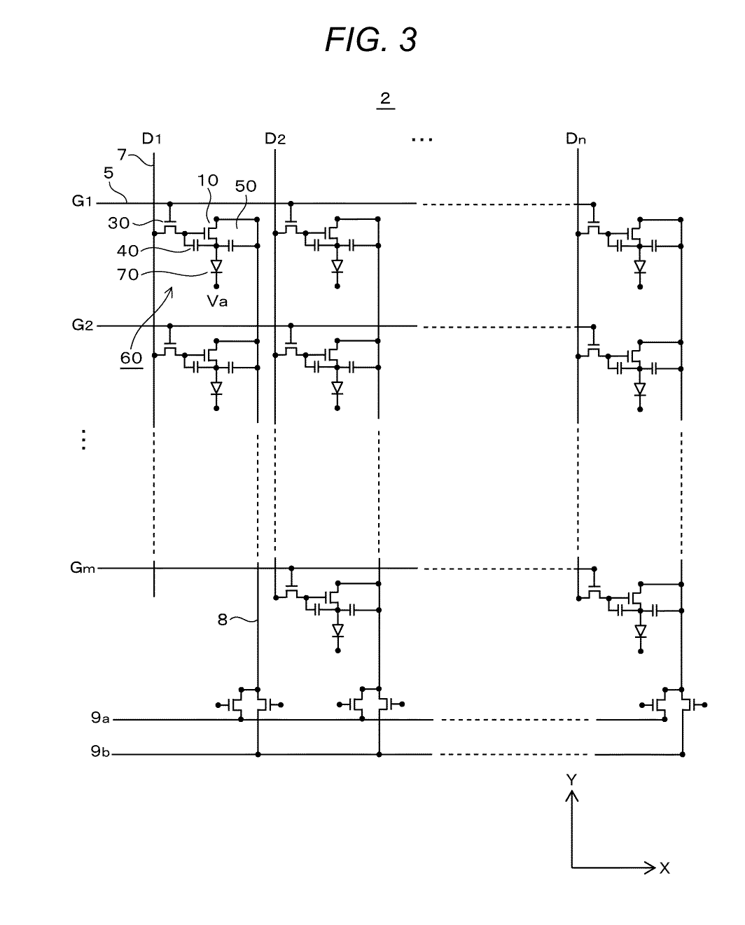

A display device 1 according to an embodiment is an active matrix drive OLED display device including a switching device and an organic light-emitting diode element formed of a thin film transistor. FIG. 2 is a schematic block diagram of the overall layout of the display device according to the embodiment. FIG. 3 is an equivalent circuit diagram of an active matrix array configuring a display unit according to the embodiment.

As illustrated in FIG. 2, in the display device 1, a display unit 2 is provided almost in the center part of an insulating substrate 6 such as a glass substrate and a plastic substrate. The substrate 6 includes a first side extended in a first direction (an X-direction) and a second side extended in a second direction (a Y-direction) in a planar view. In FIG. 2, on the upper side of the display unit 2, a data drive circuit 3 is disposed which outputs an image signal to a data line 7 extended in the second direction (the Y-direction), and on the left side, a scan driver circuit 4 is disposed which outputs a scanning signal to a gate line 5 extended in the first direction (the X-direction). The data drive circuit 3 and the scan driver circuit 4 are configured of a shift register circuit, a level shifter circuit, an analog switch circuit, and the like formed of a circuit using thin film transistors (TFTs). Moreover, a potential line 8 is extended and disposed in the direction the same as the data line 7. The potential line 8 is connected to potential supply lines 9a and 9b through a switching device.

In the display device 1, as similar to an active matrix drive liquid crystal display device, a plurality of the gate lines (the scanning signal lines) 5 is provided on the substrate 6, and a plurality of the data lines (the data signal lines) 7 is provided, which is extended in the direction (the Y-direction) crossing the extending direction of the gate lines 5 (the X-direction). As illustrated in FIG. 3, a pixel 60 is disposed at places at which m of gate lines Gl, G2, to Gm intersect with n of data lines D1, D2, to Dn in a matrix configuration. The pixels 60 include an organic light-emitting diode element (a light emitting element) 70, a storage capacitor 40, a pixel capacitor 50, a switching transistor 30 formed of a TFT, and a driver transistor 10 formed of a TFT. In the switching transistor 30, the gate electrode is connected to the gate line 5, the source electrode is connected to the data line 7, and the drain electrode is connected to the storage capacitor 40. Although the electrode connected to the data line 7 is sometimes called a drain electrode, in the present disclosure, the electrode is referred to as a source electrode. Although the electrode connected to the storage capacitor 40 is sometimes called a source electrode, in the present disclosure, the electrode is referred to as a drain electrode. In the driver transistor 10, the gate electrode is connected to the storage capacitor 40, the source electrode is connected to the potential line 8 extended in the direction the same as the data line 7 (the Y-direction), and the drain electrode is connected to one electrode (the anode) of the organic light-emitting diode element 70. Moreover, the other electrode (the cathode) of the organic light-emitting diode element configuring the light emitting element 70 is connected to a power supply line (not illustrated) shared by all pixels, and the potential is maintained at a predetermined potential Va.

In driving the pixel 60, a turn-on voltage is in turn supplied from the gate line G1 in the first row, and this voltage (a scanning signal) is in turn supplied to m rows of the gate lines Gl, G2, to Gm for one frame time. The scanning signal brings the switching transistor 30 into the ON state, and then an image signal is written on the storage capacitor 40 from the data line through the switching transistor 30. In other words, in the driving method, in the period in which the turn-on voltage is supplied to a certain gate line, all the switching transistors connected to the data lines Dl, D2, to Dn are turned into the conducting state, and a data voltage is supplied to n columns of the data lines D1, D2, to Dn in synchronization with the conduction.

The data voltage is stored on the storage capacitor 40 in the period in which the turn-on voltage is supplied, and the potential of the gate electrode of the driver transistor 10 is maintained nearly at a potential corresponding to the image signal for one frame time by the storage capacitor 40 even though the switching transistor 30 is brought into the OFF state. The voltage value of the storage capacitor regulates the gate voltage of the driver transistor 10, and thus the value of the current carried through the driver transistor 10 is controlled by the regulation, and the light emission of the organic light-emitting diode element 70 is controlled. The halt of light emission is implemented by bringing the driver transistor 10 into the OFF state.

In other words, the voltage corresponding to image information is applied through the data line 7 in synchronization with the application of the turn-on voltage to the gate line 8 corresponding to the pixel 60 whose light emission quantity has to be controlled, so that the light emission quantity of the pixel 60 can be controlled. Therefore, the light emission quantity of a plurality of pixels configuring the display unit 2 is controlled according to image information, so that a desired image can be displayed.

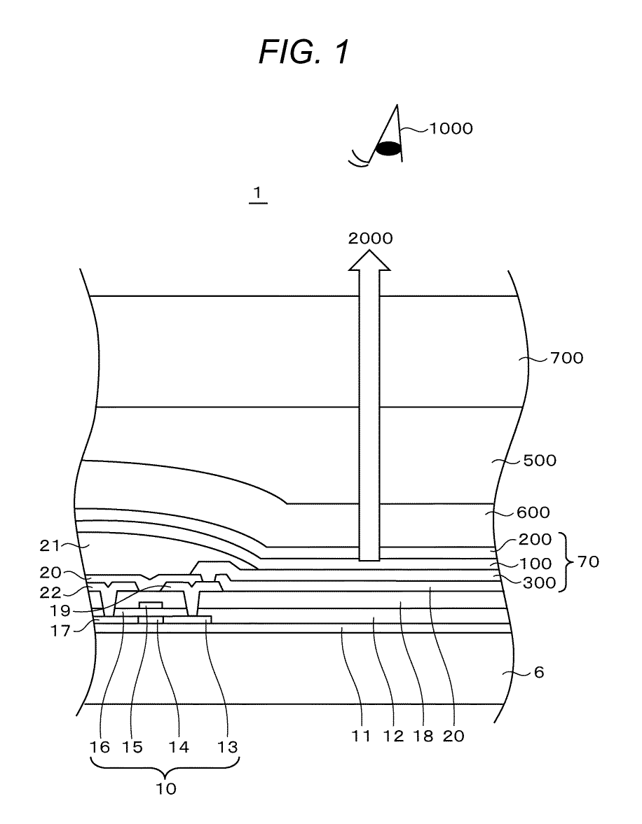

Next, the structure in the vicinity of a single pixel of the display device 1 will be described with reference to FIG. 1. FIG. 1 is a schematic cross sectional view of the vicinity of a single pixel in the cross sectional structure of the display device according to the embodiment. The embodiment is a so-called top emission OLED display device in which light is extracted from the direction opposite to the substrate 6 on which the organic light-emitting diode element 70 is formed. In other words, in the display device 1, light is emitted to the upper side (the transparent substrate 700 side) in FIG. 1, and an observer 1000 sees light 2000.

The display device 1 includes the switching devices (the driver transistor 10 and the switching transistor 30, which are not illustrated in FIG. 1) on the insulating substrate 6 such as a glass substrate and a plastic substrate. The switching devices such as the driver transistor 10 and the switching transistor 30 configuring the pixel circuit are configured of a thin film transistor (TFT). The thin film transistor includes a gate insulating film 16, a gate line layer 15, a first interlayer insulating film 18, a source electrode layer 22, a drain electrode layer 19, and a second interlayer insulating film 20 on a polysilicon layer including a source region 17, a drain region 13, a channel polysilicon layer 14, and so on. Moreover, in the case where the substrate 6 is a glass substrate, a first base film 11 formed of a SiNx (silicon nitride) film, for example, is included between the thin film transistor and the substrate 6 for preventing the intrusion of ions such as Na (sodium) and K (potassium) into the channel polysilicon layer 14 and the gate insulating film 16, and a second base film 12 formed of a SiOx (silicon oxide) film, for example, is included between the first base film 11 and the polysilicon layer.

A lower electrode 300 configuring the organic light-emitting diode element 70 is formed in an island shape so as to cover a portion to be a luminous region of the pixel. In the formation, the lower electrode 300 is connected to the drain electrode 19 through a hole penetrated through the second interlayer insulating film 20.

A third interlayer insulating film 21 including an opening corresponding to the luminous region of the pixel is formed on the peripheral part of the lower electrode 300 and a non-luminous region such as the driver transistor 10, the data line 7, which is not illustrated in FIG. 1, and the gate line 8, which is not illustrated in FIG. 1. In the present disclosure, in the following, the third interlayer insulating film 21 is also referred to as the bank 21.

Although an organic film 100 including the light emitting layer is formed on the lower electrode 300 so as to cover the entire surface of the display unit 2, the organic film 100 is isolated from the lower electrode 300 by the bank 21 on the regions other than the luminous region. An upper electrode 200 is formed on the organic film 100 on the entire surface of the display unit 2. The upper electrode 200 and the lower electrode 300 function as the anode or the cathode.

Such a film can be used for the organic film 100 of the organic light-emitting diode element 70 that an electron transport layer, a light emitting layer, and a hole transport layer are stacked between the upper electrode 200 and the lower electrode 300 from the cathode (the upper electrode 200, for example) side. This organic light-emitting diode element is one in which a direct current voltage is applied across the upper electrode 200 and the lower electrode 300, holes injected from the anode (the lower electrode 300, for example) side reach the light emitting layer through the hole transport layer, electrons injected from the cathode side reach the light emitting layer through the electron transport layer, and the electrons are recombined with the holes to emit light at a predetermined wavelength here. It is noted that a material that can be used for both of the light emitting layer and the electron transport layer may be used for the organic film 100 of the organic light-emitting diode element 70. Moreover, such a film may be used that an anode buffer layer or a hole injection layer is disposed between the anode and the hole transport layer.

It is noted that it is desirable that the lower electrode 300 be configured of a material of a high light reflectance in order to improve the use efficiency of light emitted from the light emitting layer. For the organic film 100, such a material or a structure is adopted in which a predetermined voltage is applied across the anode and the cathode to carry an electric current and then white light emission is obtained. For the organic light-emitting diode element 70 that implements white light emission, there are methods in which a plurality of light emitting layers in different light emission colors is stacked in a structure called a multi-photon and in which dies in different light emission colors are doped into a single light emitting layer. For any methods, it is desirable to use one that a high luminous efficiency is provided and white light emission of a long lifetime is obtained for the white organic light-emitting diode element 70. Furthermore, the organic film 100 is configured of a plurality of layers including the light emitting layer, the hole transport layer, and the electron transport layer, and may include an inorganic layer in some cases.

A sealing material 600 is formed on the upper electrode 200 so as to cover at least the entire surface of the display unit. Desirably, the sealing material 600 has a high gas barrier property and transmits visible light in order not to enter moisture, for example, into the organic light-emitting diode element 70. To this end, the sealing material 600 may be implanted by using a closely packed inorganic film such as a silicon nitride film or a stacked film formed of an inorganic film and an organic film.

A transparent substrate 700 formed with a color filter and a black matrix, not illustrated, is disposed on the sealing material 600. In the disposition, solid sealing is provided in which a transparent filler 500 made of a polymeric material is filled between the sealing material 600 and the transparent substrate 700 for enclosure. Alternatively, it may be fine that an inert gas such as nitrogen is filled between the sealing material 600 and the transparent substrate 700, and the substrate 6 and the peripheral part of the transparent substrate 700 are enclosed and sealed with a sealing material.

In the embodiment, the display device will be described in which an organic light-emitting diode element that emits white light is used for the organic light-emitting diode element 70 and full color display is implemented in combination with color filters corresponding to three primary colors. However, the present disclosure is not limited thereto.

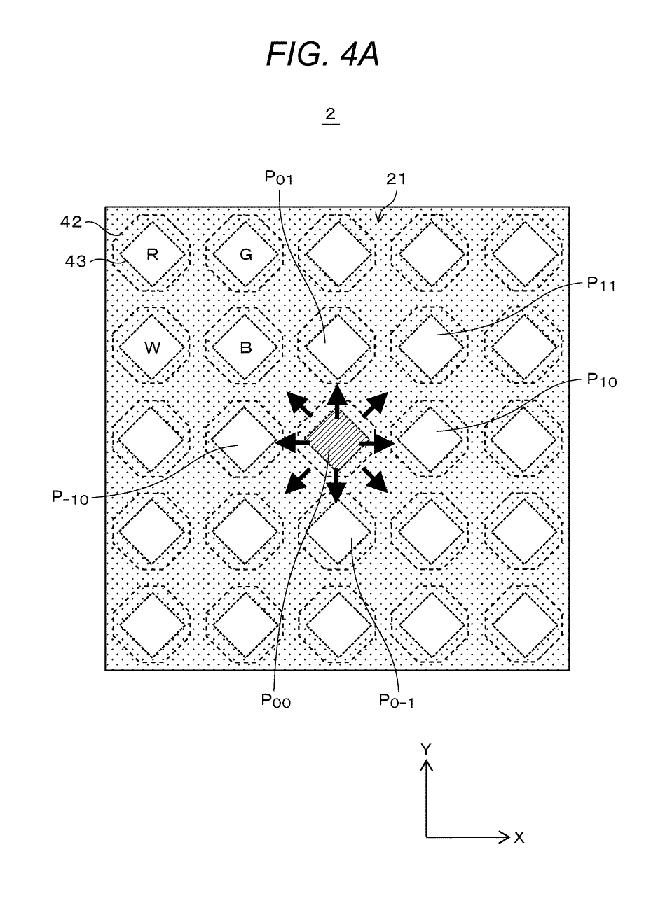

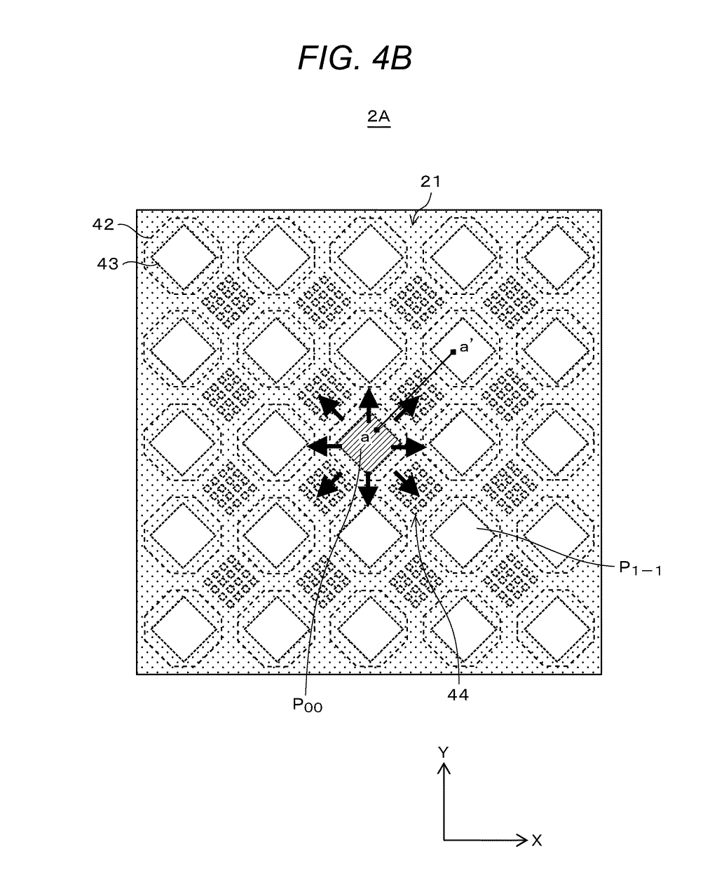

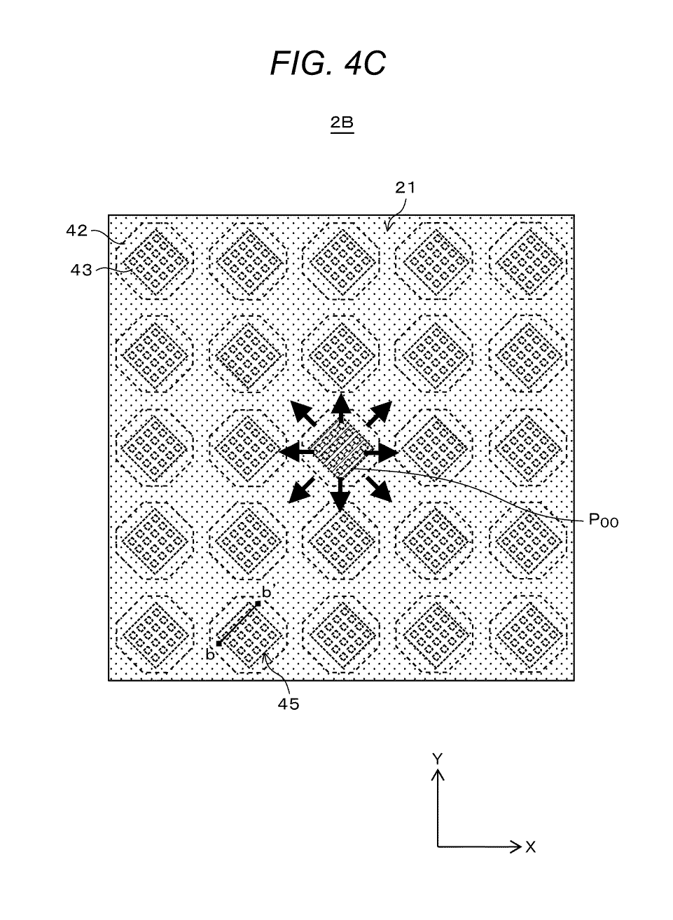

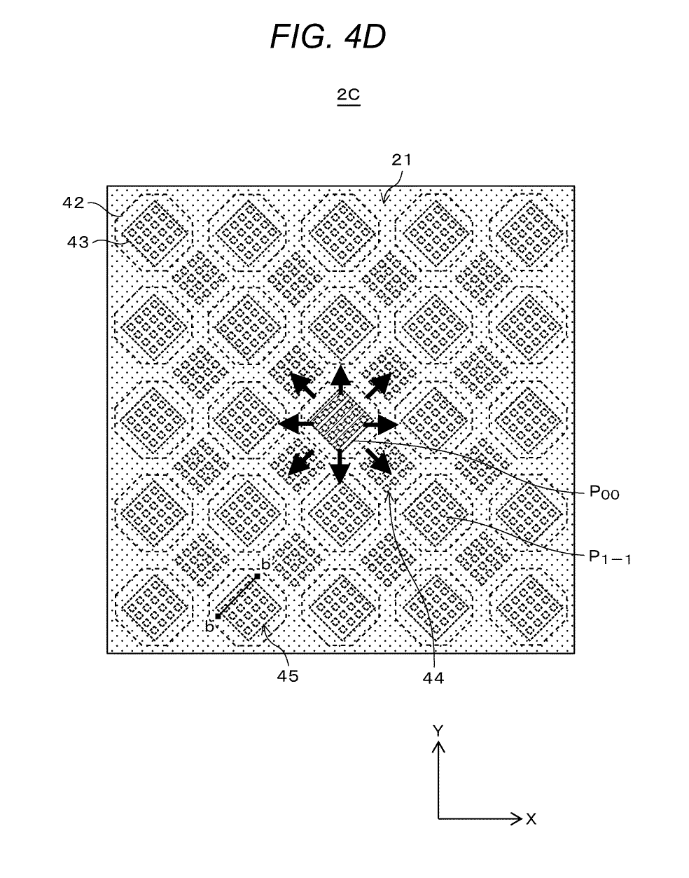

FIG. 4A is a partial plan view of the display unit according to the embodiment. The display unit 2 includes a pixel that exhibits white (W) color for reducing the power consumption of the display device in addition to pixels for red, green, and blue. In the display unit 2, white light emitting elements are disposed in a matrix configuration in a predetermined order, a color filter that transmits red (R) light is provided for a red pixel that exhibits red, a color filter that transmits green (G) light is provided for a pixel that exhibits green, and a color filter that transmits blue (B) light is provided for a pixel that exhibits blue on the light extraction side of the light emitting elements. It is noted that although it is unnecessary to provide a color filter for the pixel that exhibits white color, a color filter may be disposed for adjusting white chromaticity as necessary. It may be fine that colors are applied to the color filters by publicly known techniques such as dyeing, pigment dispersion, and printing.

The shape of a pixel electrode 42 is an octagonal shape, and the shape of a pixel opening (a bank opening) 43 is a square shape. The bank opening 43 according to the embodiment is tilted at an angle of 45° to the bank opening 63 according to the comparative example in FIG. 6. The directions of the line segments connecting the centers of the most closely adjacent pixels located as sandwiching a pixel having the bank opening 43 are the X-direction and the Y-direction. The vertices of the bank openings 43 of the most closely adjacent pixels face each other. A plane layout illustrated in FIG. 4A is adopted, so that light leakage from the pixels P₀₁, P₀₋₁, P₁₀, and P₁₀ most closely adjacent to the luminous pixel P₀₀ can be suppressed. This is because the direction of the line segment formed by the bank edge is at an angle including an angle of 45° to the direction of the adjacent pixel, and the directions are not orthogonal to each other.

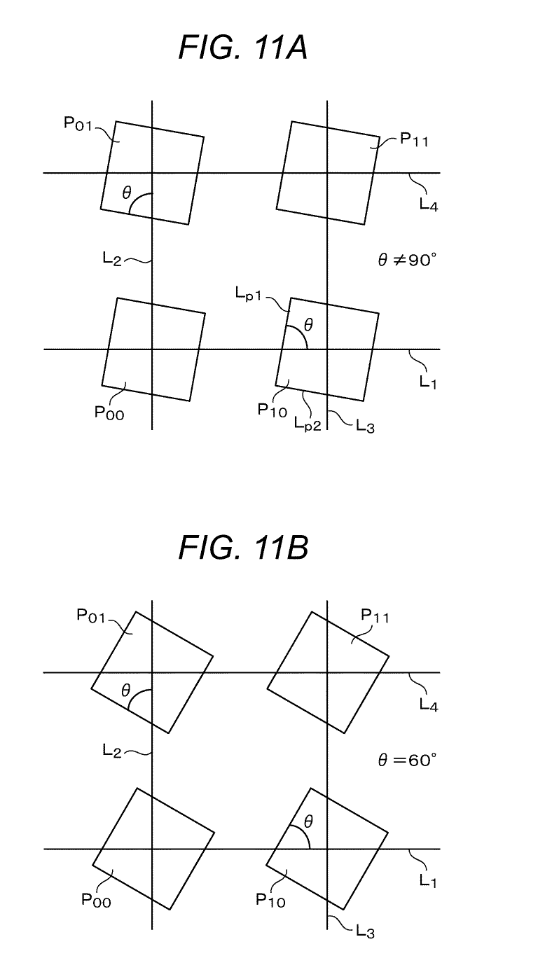

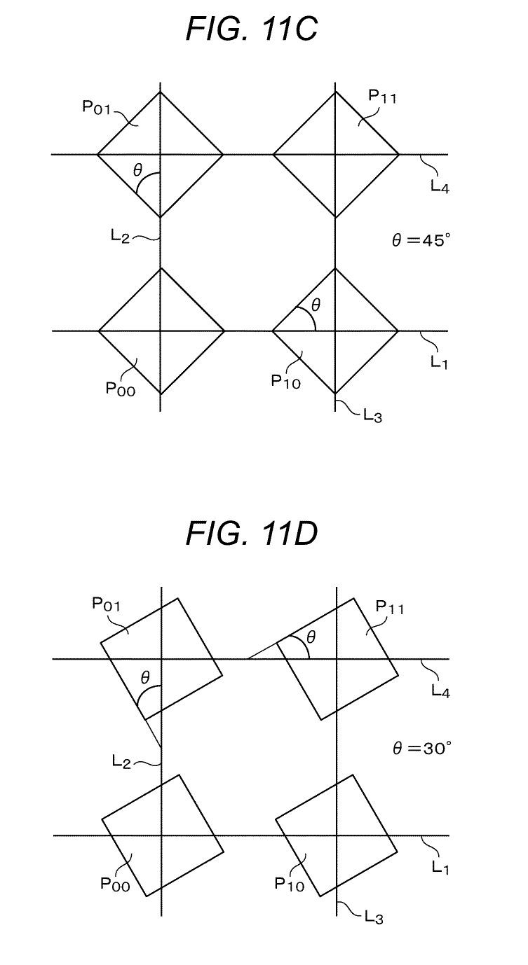

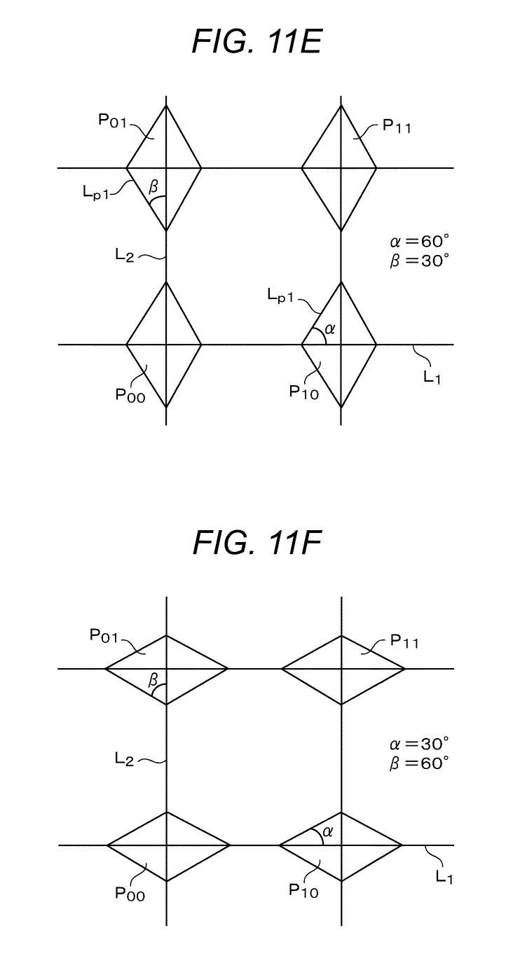

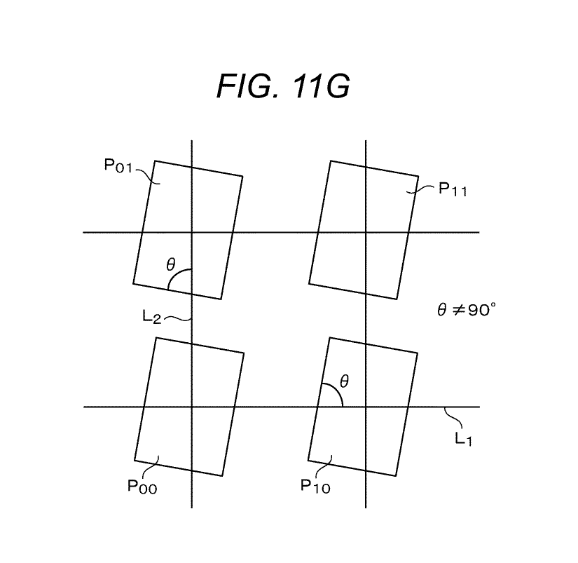

The shape of the bank opening 43 is not limited to the shape that a square is tilted an angle of 45°, and such an effect can be obtained even in shapes as illustrated in FIGS. 11A to 11G that the light leakage from the adjacent pixels is reduced although not at the maximum. The same things can be applied to exemplary modifications below. FIG. 11A is a shape that a square is slightly tilted, and it may be fine that an angle θ is not an angle of 90° (the angle θ may be an acute angle or an obtuse angle). Here, the angle θ is an angle formed by line segments formed by the bank edges and line segments L₁, L₂, L₃, and L₄ that connect the centers of the most closely adjacent pixels located as sandwiching the pixel having the bank opening 43. For example, the angle θ is an angle formed by the line segment L₁ and a line segment Lₚ₁ of the pixel P₁₀. It is noted that an angle formed by the line segment L₁ and a line segment Lₚ₂ of the pixel P₁₀ is an angle 90°-θ. The most closely adjacent pixels are the pixel P₀₀ and the pixel P₁₀, the pixel P₁₀ and the pixel P₁₁, the pixel P₁₁ and the pixel P₀₁, and the pixel P₀₁ and the pixel P₀₀. FIG. 11B is a shape that a square is tilted in the case of the angle θ=60°, FIG. 11C is a shape that a square is tilted in the case of the angle θ=45°, and FIG. 11D is a shape that a square is tilted in the case of the angle θ=30°. FIG. 11E is a vertically oriented diamond in the case of an angle α=60° and an angle β=30°. Here, the angle a is an angle formed by the line segment L₁ and a line segment L_{P1} formed by the bank edge of the pixel P₁₀, and the angle βis an angle formed by the line segment L₂ and a line segment L_{P1} formed by the bank edge of the pixel P₀₁. FIG. 11E is a horizontally oriented diamond in the case of the angle a α=30° and the angle β=60°. FIG. 11G is a shape that a rectangle is slightly tilted. Preferably, the angles θ, α, and β are an angle of 45°. However, the angles θ, α, and β are an angle ranging from about 30° to 60°.

It is noted that as described above (the description with reference to FIG. 7), a high effect of suppressing light leakage from the adjacent pixels is the case where an approximately linear bank edge (a line segment) is at an angle including an angle of 45° with respect to the direction of the luminous pixel, that is, at an angle ranging from 27° to 63°, so that it is likely that the highest effect of suppressing light leakage is obtained in FIG. 11C among FIGS. 11A to 11G.

On the other hand, between pixels whose approximately linear bank edges (line segments) are nearly in parallel with each other (between the pixel P₀₀ and the pixel P₁₁, for example), the direction of the line segment of the bank edge is nearly orthogonal to the direction of the pixel. The distance between these pixels is longer than the distance between the pixels most closely adjacent to each other, so that light leakage can be reduced more or less. However, although the distance between these pixels is longer than the distance between the pixels most closely adjacent to each other, it is likely that light leakage occurs.

### FIRST EXEMPLARY MODIFICATION

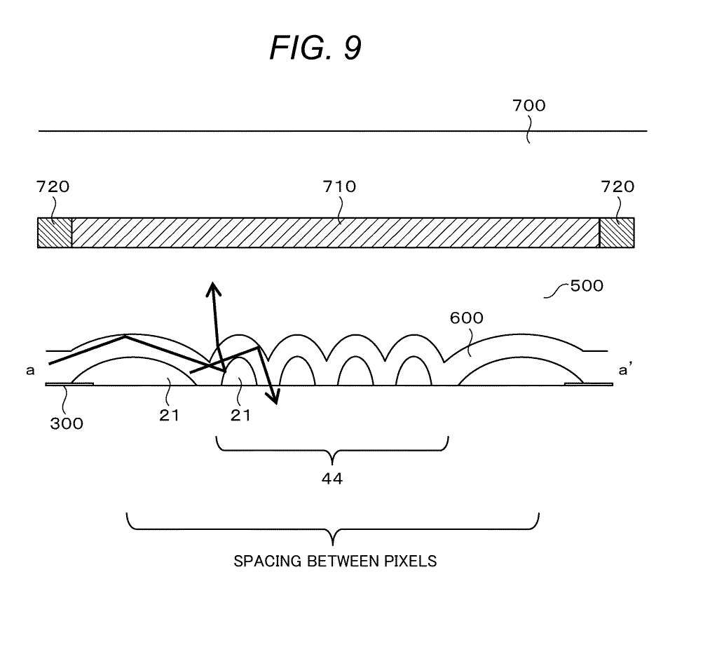

FIG. 4B is a partial plan view of a display unit according to a first exemplary modification. As illustrated in FIG. 4B, in a display unit 2A, a light leakage prevention structure 44 having projections and depressions is formed between the pixels that the directions of the line segments formed by the bank edges are nearly in parallel with each other (between the pixel P₀₀ and the pixel P₁₋₁, for example). The display unit 2A is the same as the display unit 2 according to the embodiment except that the light leakage prevention structure 44 is included. FIG. 9 is a schematic diagram of a partial cross section of the schematic structure of the light leakage prevention structure. FIG. 9 is a diagram of a cross section taken along line a-a′ in FIG. 4B. It is fine that the projections and depressions of the light leakage prevention structure 44 are formed using the insulating film 21 formed on the peripheral part of the lower electrode 300. In other words, the projections and depressions of the light leakage prevention structure 44 are formed in the same layer as the bank 21, and the sealing material 600 and the filler 500 are stacked on the light leakage prevention structure 44. On this account, it is unnecessary to increase processes particularly, and manufacturing costs are not affected.

The light leakage prevention structure 44 is formed in such a manner that the approximately linear portion (a line segment) of the projections and depressions is nearly in parallel with the direction in which the bank edge shape of the pixel is an approximately linear portion (a line segment). In this case, most of light that leaks between pixels, between which the light leakage prevention structure 44 is formed, changes the traveling direction by the light leakage prevention structure 44, and the light is absorbed by a black matrix 710 formed on the transparent substrate 700, or scatters toward the substrate 6 side, so that light leakage to the adjacent pixel can be suppressed. It is noted that a color filter 720 is formed on the transparent substrate 700.

### SECOND EXEMPLARY MODIFICATION

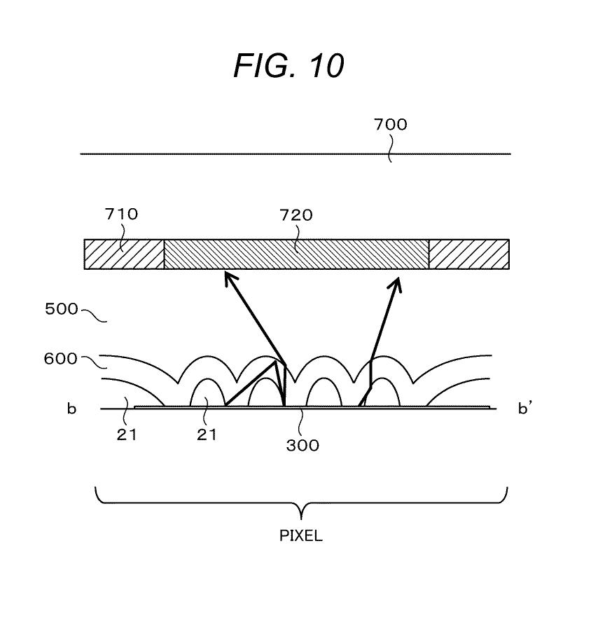

FIG. 4C is a partial plan view of a display unit according to a second exemplary modification. As illustrated in FIG. 4C, in a display unit 2B, a light extraction structure 45 having projections and depressions is formed in the luminous region of the pixel. The light extraction structure 45 may be formed on the lower electrode 300 with a material in the same layer as the bank 21. The display unit 2B is the same as the display unit 2 according to the embodiment except that the light extraction structure 45 is included. FIG. 10 is a schematic diagram of a partial cross section of the schematic structure of the light extraction structure. FIG. 10 is a diagram of a cross section taken along line b-b′ in FIG. 4C. the projections and depressions of the light extraction structure 45 are formed in the same layer as the bank 21, and the organic film 100, the upper electrode 200, the sealing material 600, and the filler 500 are stacked on the light extraction structure 45. On this account, it is unnecessary to increase processes particularly, and manufacturing costs are not affected.

In this case, since the lower electrode 300 is insulated from the organic film 100 at the projections of the projections and depressions, the area of light emission is reduced accordingly. In other words, light is emitted only in the depressions.

It is noted that it is important here that the approximately linear portion of the projections and depressions is nearly in parallel with the direction in which the bank edge shape of the pixel is in an approximately linear shape. The reason is as follows.

In the case where the light extraction structure 45 having projections and depressions, for example, is formed in the luminous region of the pixel, there is concern that the light extraction structure 45 extracts light emitted from the adjacent pixel, and the light leaks to cause a blur or color mixture. However, the approximately linear portion (a line segment) of the projections and depressions is formed nearly in parallel with the direction in which the bank edge shape of the pixel is an approximately linear portion (a line segment) as in the light extraction structure 45 according to the exemplary modification, and light extraction from the adjacent pixel can be suppressed, so that it is possible to reduce blurred display or color mixture.

It is noted that the projections and depressions for extracting light is not limited to the exemplary modification. For example, it may be fine that projections and depressions are formed on the under layer of the lower electrode, the organic light-emitting diode element is formed on the layer, and the light emission portion itself is formed in projections and depressions.

### THIRD EXEMPLARY MODIFICATION

FIG. 4D is a partial plan view of a display unit according to a third exemplary modification. A display unit 2C according to the third exemplary modification is one that the display unit 2A according to the first exemplary modification is combined with the display unit 2B according to the second exemplary modification. In other words, in the display unit according to the third exemplary modification, the light leakage prevention structure 44 having projections and depressions is formed between pixels whose directions of the line segments formed by the bank edges are nearly in parallel with each other (between the pixels P₀₀ and the pixel P₁₋₁, for example), and the light extraction structure 45 having projections and depressions is formed in the luminous region of the pixel.

### FOURTH EXEMPLARY MODIFICATION

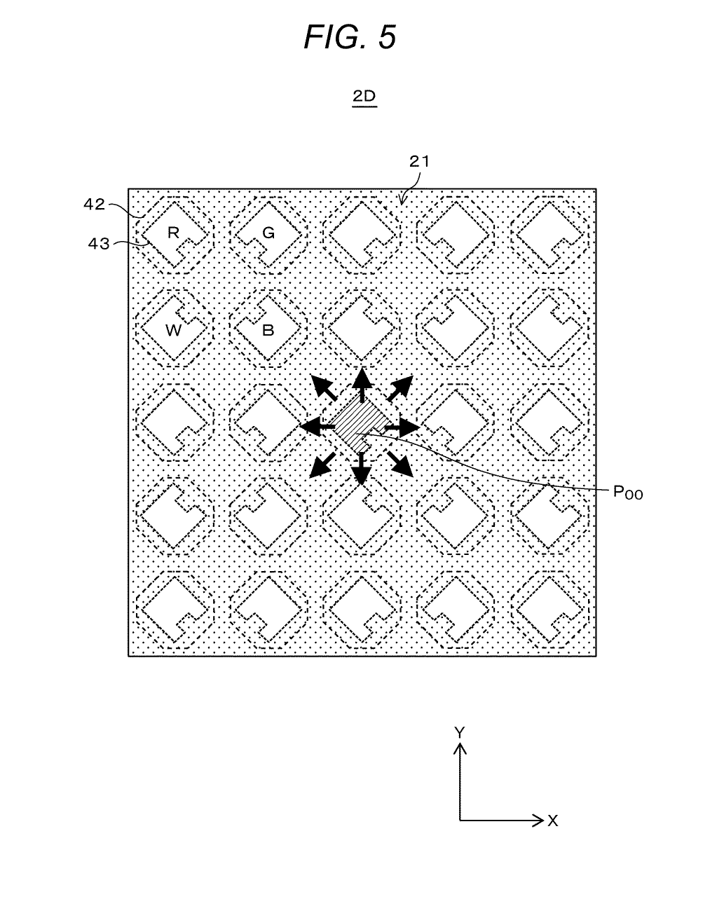

FIG. 5 is a partial plan view of a display unit according to a fourth exemplary modification. In the embodiment, the case is described where the shape of the light emission portion of the pixel, that is, the bank edge shape is a rectangle. However, the present disclosure is not limited thereto. For example, as illustrated in FIG. 5, the shape of the luminous region of the pixel, that is, the plane shape of the bank edge may be a U-shape. Also in this case, such a planar structure may be adopted in which the directions of all the line segments formed by the bank edges are tilted at an angle of about 27° to 63° with respect to the direction of the most closely adjacent pixels. In this case, as similar to the embodiment, it is possible that light leakage from the adjacent pixels is suppressed and color mixture is suppressed. In other words, the luminous region of the pixel, that is, the plane shape of the bank edge may be an L-shape, or other shapes. It is noted that it is without saying that it may be fine that the exemplary modification is combined with the first exemplary modification, the exemplary modification is combined with the second exemplary modification, and the exemplary modification is combined with the third exemplary modification.

As described above, the disclosure made by the inventors is described specifically based on the embodiment and the exemplary modifications. However, it is without saying that the present disclosure is not limited to the embodiment and the exemplary modifications and can be modified variously.

What is claimed is:

1. A display device comprising:
a substrate including a main face; and
a plurality of pixels two-dimensionally configured on the main face of the substrate, the pixels including a luminous region,
wherein: the pixels individually has a light emitting element including a lower electrode, a light emitting layer, and an upper electrode;
an insulating film is formed above the light emitting element;
the luminous region is exposed through an opening of the insulating film, and a shape of the luminous region is defined by an edge of the opening;
the pixels includes a first pixel having a first luminous region and two second pixels most closely adjacent to the first pixel and located as sandwiching the first pixel; and
an acute angle or an obtuse angle is formed by a direction in which one side of the edge of the opening exposing the first luminous region is extended and a direction of a linear line connecting centers of the two second pixels.

2. The display device according to claim 1, wherein an angle formed by the direction in which the one side of the edge is extended and the direction of the linear line connecting the centers of the two second pixels is an angle ranging from 27° to 63°.

3. The display device according to claim 1, wherein an angle formed by the direction in which the one side of the edge is extended and the direction of the linear line connecting the centers of the two second pixels is an angle of 45°.

4. The display device according to claim 1,
wherein: the opening exposing the first luminous region is in a rectangular shape, and
the opening has a pair of vertices individually facing the two second pixels.

5. The display device according to claim 1,
wherein: the plurality of pixels includes a third pixel facing the one side of the edge; and
the insulating film between the first pixel and the third pixel has a projection and a depression.

6. The display device according to claim 5,
wherein: an outline of the projection and the depression includes a linear portion; and
the linear portion is formed in parallel with the one side of the edge.

7. The display device according to claim 1, wherein a projection and a depression are formed on the luminous region.

8. The display device according to claim 7,
wherein: an outline of the projection and the depression formed on the luminous region includes a linear portion; and
the linear portion is formed in parallel with the one side of the edge.

9. A display device comprising:
a substrate including a first side extended in a first direction and a second side extended in a second direction intersecting with the first direction in a planar view; and
a plurality of pixels configured in an array configuration on a main face of the substrate,
wherein: the pixels individually has a light emitting element including a lower electrode, a light emitting layer, and an upper electrode;
an insulating film is formed above the light emitting element;
the luminous region is exposed through an opening of the insulating film, and a shape of the luminous region is defined by an edge of the opening;
the plurality of pixels includes a first pixel having a first luminous region and two second pixels most closely adjacent to the first pixel and located as sandwiching the first pixel;
an acute angle or an obtuse angle is formed by a direction in which one side of the edge of the opening exposing the first luminous region is extended and a direction of a linear line connecting centers of the two second pixels; and
an acute angle or an obtuse angle is formed by a direction in which one side of the edge is extended and the first direction and the second direction.

10. The display device according to claim 9, wherein an angle formed by the direction in which the one side of the edge is extended and the direction of the linear line connecting the centers of the two second pixels is an angle ranging from 27° to 63°.

11. The display device according to claim 9, wherein an angle formed by the direction in which the one side of the edge is extended and the direction of the linear line connecting the centers of the two second pixels is an angle of 45°.

12. The display device according to claim 9,
wherein: the opening exposing the first luminous region is in a rectangular shape, and
the opening has a pair of vertices individually facing the two second pixels.

13. The display device according to claim 11,
wherein: the plurality of pixels includes a third pixel facing the one side of the edge, and
the insulating film between the first pixel and the third pixel has a projection and a depression.

14. The display device according to claim 13,
wherein: an outline of the projection and the depression includes a linear portion, and
the linear portion is formed in parallel with the one side of the edge.

15. The display device according to claim 9, wherein a projection and a depression are formed on the luminous region.

16. The display device according to claim 15,
wherein: an outline of the projection and the depression formed on the luminous region includes a linear portion, and
the linear portion is formed in parallel with the one side of the edge.
